(19) United States
(12) Patent Application Publication
(10) Pub. No.: US 2010/0126407 A1
(43) Pub. Date: May 27, 2010

(54) SILICA GLASS CRUCIBLE AND METHOD FOR PULLING SINGLE-CRYSTAL SILICON

(75) Inventors: Hiroshi Kishi, Akita-shi (JP); Masanori Fukui, Akita-ken (JP)

Correspondence Address: GREENBLUM & BERNSTEIN, P.L.C., 1950 ROLAND CLARKE PLACE, RESTON, VA, 20191, US

(73) Assignees: JAPAN SUPER QUARTZ CORPORATION, Akita-ken (JP); SUMCO CORPORATION, Tokyo (JP)

(21) Appl. No.: 12/694,661

(22) Filed: Jan. 27, 2010

Related U.S. Application Data
(62) Division of application No. 12/251,614, filed on Oct. 15, 2008.

(30) Foreign Application Priority Data
Mar. 31, 2006 (JP) 2006-096326

(51) Int. Cl. C30B 15/30

(52) U.S. Cl. 117/28

(57) ABSTRACT

A silica glass crucible used for pulling single-crystal silicon, which includes a cylindrical straight body part, a bottom part and a curved part located between the straight body part and the bottom part, wherein the curvature radius of the inner wall surface of the curved part is 100 to 240 mm. Variation of the wall thickness W of the curved part is preferably 0.1 to 1.4 mm/cm.

### CROSS-REFERENCE TO RELATED APPLICATIONS

This application is a divisional of U.S. patent application Ser. No. 12/251,614, filed Oct. 15, 2008, the content of which is expressly incorporated by reference herein in its entirety.

### BACKGROUND OF THE INVENTION

1. Technical Field

The present invention relates to a silica glass crucible which is used for pulling single-crystal silicon, and a method for pulling single-crystal silicon.

2. Background Art

Single-crystal silicon which is used for a semiconductor material is mainly manufactured by pulling up from molten polycrystalline silicon, and a silica glass crucible is used for holding a polycrystalline silicon melt. The silica glass crucible is put in a carbon susceptor and heated from the high temperature surroundings. In order to uniformly transfer this heat, a silica glass crucible whose outer layer is a translucent layer having bubbles and whose inner surface is a transparent layer having substantially no bubbles, is disclosed in Patent Document 1: Japanese Unexamined Patent Publication No. 06-92779. However, in the case of manufacturing a silica glass crucible by a rotary mold method, silica powder which has accumulated on the inner surface of the mold is heated and melted, vitrified silica is subjected to downward force due to its own weight, and as a result, the curved part of the crucible tends to grow in thickness. Consequently, there is a possibility that the heat transfer at a curved part of the crucible differs from the surrounding area thereby becoming less uniform.

Meanwhile, with regard to the curved part of a silica glass crucible, when a crucible is used under high temperature for a long period of time, the glass strength is gradually lowered, a curved part of the crucible is subjected to intense local stress due to its own weight and then deforms to decrease the yield of single crystal in some cases. In order to prevent this, a silica glass crucible in which the strength of a curved part of the crucible is enhanced by the setting wall thickness of the curved part as 1.5 to 1.8 times thicker than that of the straight body part of the crucible is disclosed in Patent Document 2: WO 02/014587. However, since a lower part below the curved part of the crucible is within a range where the surface area of a silicon melt gradually decreases when the liquid level of the silicon melt is lowered due to the pulling of a single-crystal silicon, there is a problem that silicon being pulled becomes polycrystalline when the surface area of this liquid level rapidly decreases. Thus, although the curved part of a crucible is thickened, if a curvature radius of the curved part is inappropriate, the yield of single crystal cannot be increased.

The present invention has resolved the above-mentioned Conventional problems in a silica glass crucible for pulling single-crystal silicon, and provides a silica glass crucible which can suppress polycrystallization upon pulling single-crystal silicon and increase the yield of single crystal by being adjusted in a curvature radius of the curved part of the crucible, more preferably the change of wall thickness to a predetermined range.

### SUMMARY OF THE INVENTION

The present invention relates to a silica glass crucible and a method for pulling single-crystal silicon, which include any one of the constitutions described below in order to solve the above-mentioned problems,

(1) A silica glass crucible which is used for pulling single-crystal silicon is characterized in that the curvature radius R1 of the inner wall surface of a crucible curved part is 100 to 240 mm. Here, the crucible curved part refers to a curved region which has a relatively small curvature radius and is an area between a cylindrical straight body part and a bottom part having a large curvature radius. Furthermore, the curvature radius of the crucible curved part is the minimum curvature radius of an inner peripheral surface of the curved part.

(2) The silica glass crucible described in the above (1), in which variation of the wall thickness W of the crucible curved part is 0.1 to 1.4 mm/cm. Here, the variation of wall thickness W refers to the amount of change in wall thickness W when a measurement location is moved in a direction along an axis of the crucible.

(3) The silica glass crucible described in the above (1), in which variation of the wall thickness W of the curved part is 0.2 to 0.5 mm/cm.

(4) A method for pulling single-crystal silicon using the silica glass crucible described in any one of the above (1) to (3), which includes the steps of melting polycrystalline silicon in the silica glass crucible; immersing a seed composed of single-crystal silicon in the molten silicon; and forming a single-crystal silicon ingot by pulling the seed while rotating the silica glass crucible.

For the silica glass crucible of the invention, the curvature radius of the curved part is adjusted to be within a predetermined range. Therefore, the surface area of the liquid is slowly reduced when the liquid level of molten silicon is lowered along the curved part in a process of pulling up a single-silicon crystal ingot, and thus a rapid change of the surface area hardly occurs. Moreover, when change of the wall thickness of the curved part is adjusted within a predetermined range, temperature distribution in the inner peripheral surface of the curved part becomes uniform. Consequently, silicon is difficult to polycrystallize and the yield of a single crystal can be increased upon the pulling single-crystal silicon.

“Silica” in the specification is not limited to general silica and includes any material known as a raw material for a silica glass crucible, such as silicon dioxide (silica), crystal and silica sand.

### BRIEF DESCRIPTION OF THE DRAWINGS

FIG. 1 is a longitudinal sectional view showing one embodiment of a silica glass crucible related to the invention.

FIG. 2 is a longitudinal sectional view showing a state for pulling up a single-crystal silicon ingot being pulled from a silicon melt in a silica glass crucible of one embodiment.

FIG. 3 is a longitudinal sectional view showing another embodiment of the invention.

### DESCRIPTION OF REFERENCE NUMERALS AND SIGNS

1-electrode drive mechanism, 2-carbon electrode, 3-mold, 4-drive mechanism, 5-pressure reducing passage, 6-silica deposited layer, 7-arc discharge device, 11-silica glass crucible, 12-curved part, 13-straight body part, 14-bottom part, R1-curvature radius of the inner surface of the curved part, R2-curvature radius of the inner surface of the bottom part, W-wall thickness of the curved part, S1 and S2-liquid level, 20-inner layer, 22-outer layer

### Preferred Embodiments

Hereinafter, the present invention will be illustrated in detail with reference to drawings.

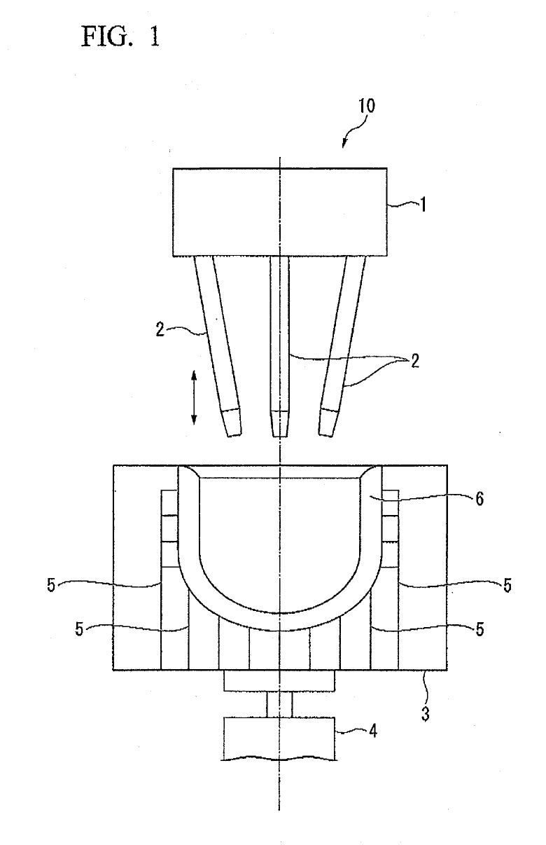

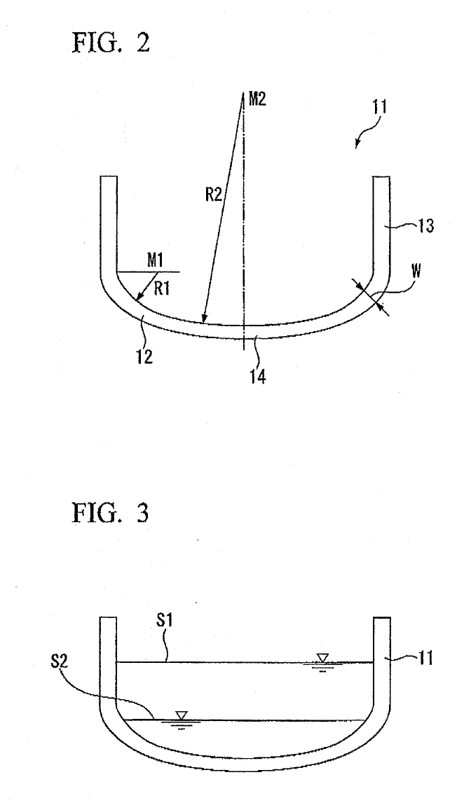

FIG. 1 is a longitudinal sectional view showing one embodiment 11 of a silica glass crucible related to the invention, and FIG. 2 is a longitudinal sectional view showing a single-crystal silicon ingot I being pull up from a silicon melt Yin a silica glass crucible 11. S1 and S2 each show the liquid level of the silicon melt Y.

The silica glass crucible 11 of this embodiment is used for pulling single-crystal silicon, and characterized in that the crucible has a straight body part 13, a bottom part 14 and a curved part 12 which is located therebetween as shown in the figure, and a curvature radius R1 of the inner wall surface of this curved part 12 is 100 to 240 mm. The straight body part 13 of the crucible is a cylindrical part having an axis C of the crucible, and extends upward from the curved part 12 as shown in the figure.

The curved part 12 of the crucible starts from the bottom end of the straight body part 13 to a point touching the bottom part 14 as shown in the figure. The curvature radius R1 of the inner wall surface of the curved part coincides with the curvature radius R2 of the inner wall surface at the bottom part at the boundary between the curved part 12 and the bottom part 14. In this embodiment, a central point M1 of the curvature radius R1 of the curved part 12 lies on the horizontal line extending from the bottom end of the straight body part 13 (that is, top end of the curved part 12) as shown in FIG. 1. Meanwhile, a central point M2 of the curvature radius R2 of the bottom part 14 lies adjacent to a point at the intersection of a center line of the crucible with a top end of the crucible.

In the case where a radius of the crucible is between 22 and 32 inches, the minimum curvature radius R1 of the curved part 12 is preferably in the range of 100 to 240 mm, and the maximum curvature radius R2 of the bottom part 14 is largely in the range of 550 to 900 mm.

Where the curvature radius R1 of the curved part 12 is smaller than 100 mm, inclination of the curved part 12 (an angle with respect to a horizontal plane) changes rapidly. Accordingly, as shown in FIG. 3, when a liquid level S1 of a silicon melt inside the crucible is gradually lowered with progress of pulling up the seed and reaches a liquid level S2 coming in contact with the curved part 12, and an area As 2 of the liquid level S2 rapidly becomes smaller than an area As 1 coming in contact with the straight body part 13, which thus has an affect on a silicon solid-liquid interface thereby readily causing polycrystallization of silicon.

Alternatively, when the curvature radius R1 of the curved part is more than 240 mm, it is not substantially different from the bottom part 14, which thus leads to a rapid change in an angle of the boundary between the straight body part 13 and the curved part 12. As a result, stress, such as the weight of the crucible, easily localized, thus it is not preferable from the viewpoint of enhancing the strength of the crucible.

More preferably, the minimum curvature radius R1 of the curved part 12 is 12 to 45% of an inside diameter of the crucible D, and the curvature radius R2 of the bottom part 14 is 60 to 220% of an inside diameter D of the crucible. Further preferably, the minimum curvature radius R1 of the curved part 12 is 15 to 35% of an inside diameter D of the crucible, and the curvature radius R2 of the bottom part 14 is 80 to 150% of an inside diameter D of the crucible.

Moreover, in a silica glass crucible 11 of this embodiment, variation of wall thickness W of the curved part 12 (the difference in wall thickness/distance between inside surfaces) is 0.1 to 1.4 mm/cm, and preferably 0.2 to 0.5 mm/cm. This variation of wall thickness refers to a value indicating a difference between the thickness of each measurement spot located within a range from a top end of the curved part 12, that is a boundary of the straight body part 13, to a boundary of the bottom part 14, and the thickness of each measurement spot located along a crucible axis line C. For example, when the wall thickness of the curved part 12 at the measurement spot X1 is W1, and the wall thickness at the measurement spot X2 distanced by a predetermined distance L in a direction along the crucible axis line C is W2, a value obtained by dividing the thickness difference (W1−W2) by the distance L is the wall thickness variation W [W=(W1−W2)/L].

When the variation of wall thickness is smaller than 0.1 mm/cm, the wall thickness of the curved part 12 becomes insufficient and a crucible 11 may deform. Alternatively, when the variation of this wall thickness is larger than 1.4 mm/cm, the difference in the wall thickness of the crucible becomes larger and heat distribution changes rapidly. Therefore, polycrystallization of silicon readily occurs, and thus the yield of single crystal decreases. The wall thickness is measured on the basis of a cross section line perpendicular to the inner wall surface.

The maximum wall thickness of the curved part 12 of the crucible is preferably one to three time(s) thicker than the average wall thickness of the straight body part 13 of the crucible, and more preferably 1.1 to 2 times. In this case, the strength of the curved part 12 of the crucible can be further enhanced.

According to the silica glass crucible 11 of this embodiment, since the change in a surface area of the liquid level of a silicon melt becomes moderate upon pulling a single-crystal silicon ingot I as shown in FIG. 2 and the heat distribution of the curved part 12 is also uniform, polycrystallization of silicon hardly occurs and the yield of single crystal can be increased.

In order to pull single-crystal silicon using the silica glass crucible 11 of this embodiment, polycrystalline silicon is melted in the silica glass crucible 11, a seed composed of single-crystal silicon (not shown in FIGS.) is immersed in a silicon melt Y, and the seed is pulled up while the silica glass crucible 11 is rotated around an axis of the crucible C, thereby forming a single-crystal silicon ingot I.

According to such a method for pulling single-crystal silicon, use of the silica glass crucible 11 provides the advantage that a rapid change of the heat distribution of the curved part of the crucible and the liquid level can be suppressed, polycrystallization when pulling single-crystal silicon in a silicon melt inside the crucible can be suppressed and the yield of single crystal can be increased.

FIG. 3 shows another embodiment of the invention. The silica glass crucible 11 of this embodiment includes an outer layer 22 which is a translucent layer having bubbles and an inner layer 20 which is a transparent layer having substantially no bubbles. Other constitutions are the same with the foregoing embodiments. The present invention can also be applied to a crucible having such a double-layered structure.

### Examples

Hereinafter, Examples and Comparative Examples according to the invention will be demonstrated together.

Single-crystal silicon was pulled up using a silica glass crucible (32 inches in diameter) as shown in FIG. 1. The results are shown in Table 1.

When a silica crucible (No. 2 or No. 3) in which the curvature radius R1 of the inner surface of the curved part 12 and a wall thickness variation W of the curved part 12 are within the range of the invention is used, the yield of the single crystal was between 78 and 83% and the pulling time was 78 to 83 hours.

On the other hand, in the case of comparative specimens (No. 1 and No. 4) whose curvature radius R1 of the inner surface was less than 100 mm or more than 240 mm, the yield of the single crystal was significantly low (as low as 40%) because polycrystallization of silicon occurred when the hot water level of a silicon melt reached the curved part R1.

Moreover, with the silica glass crucibles used for these comparative specimens, when silicon was polycrystallized in the silica glass crucible, an operation of re-pulling single crystal by melting the polycrystallized part of silicon had to be repeated. Thus, the pulling operation took longer than necessary in total by carrying out a re-melting operation, meaning that the pulling period was extended to a large extent. In addition, the pulling has to be performed within the scope of durability, and the limit of the total pulling-up time is approximately 150 hours. The pulling time in the comparative specimen No. 4 was close to the limit.

TABLE 1

| | Curved Part | | Yield of | | |
|---|---|---|---|---|---|
| | Curvature | | Single | Pulling Up | |
| | Radius R1 of | Wall Thickness | Crystal | Time | |
| No. | Inner Surface | Variation W | (%) | (hr) | Evaluation |
| 1 | 80 | 0.08 | 40 | 127 | B |
| 2 | 120 | 0.2 | 83 | 83 | A |
| 3 | 200 | 0.8 | 78 | 79 | A |
| 4 | 260 | 1.5 | 45 | 155 | B |

(NOTES)
CURVATURE (mm/cm),
WALL THICKNESS VARIATION (mm/cm)

Hereinbefore, preferred embodiments of the invention have been illustrated, but the invention is not limited thereto. Additions, omissions, substitutions, and other modifications can be made without departing from the spirit or scope of the invention. Accordingly, the invention is not to be considered as being limited by the foregoing description, and is only limited by the scope of the appended claims.

1. A method for pulling single-crystal silicon comprising:
melting polycrystalline silicon in a silica glass crucible, the silica glass crucible comprising a cylindrical straight body part, a bottom part and the curved part located between the straight body part and the bottom part, wherein a curvature radius of the inner wall surface of the curved part is 100 to 240 mm;
immersing a seed composed of single-crystal silicon in the molten polycrystalline silicon; and
forming a single-crystal silicon ingot by pulling the seed while rotating the silica glass crucible.
